(19) United States
(12) Patent Application Publication
(10) Pub. No.: US 2026/0214922 A1
(43) Pub. Date: Jul. 23, 2026

(54) Silicon carbide based-lateral power semiconductor device, and method for manufacturing same

(71) Applicant: Trinno Technology Co., Ltd., Seoul (KR)

(72) Inventors: Kwang Hoon OH, Seoul (KR); Soo Seong KIM, Seoul (KR); Jin Young JUNG, Seoul (KR); Chongman YUN, Seoul (KR)

(21) Appl. No.: 18/874,970

(22) PCT Filed: May 18, 2023
(86) PCT No.: PCT/KR2023/006755

§ 371 Date: Sep. 25, 2025

(30) Foreign Application Priority Data
Jun. 14, 2022 (KR) 10-2022-0071989

(51) Int. Cl. H10D 12/00; H10D 12/01; H10D 62/832; H10P 30/22

(52) U.S. Cl. CPC H10D 12/417; H10D 12/031; H10D 62/8325; H10P 30/22

(57) ABSTRACT

Disclosed are a silicon carbide based-lateral power semiconductor device, and a method for manufacturing same. The silicon carbide-based lateral power semiconductor device includes: a substrate of a first conductive type made of silicon carbide; a drift layer of a first conductive type formed on the upper surface of the substrate and having a relatively low impurity concentration in comparison to the substrate; a body region of a second conductive type formed on an upper layer of the drift layer; a collector region of a second conductive type formed on the upper layer of the drift layer and laterally spaced apart from the body region; and a trench buffer zone disposed between the body region and the collector region to block the lateral expansion of an electric field.

### FIELD OF THE INVENTION

The present invention relates to a silicon carbide-based lateral power semiconductor device and a method for manufacturing the same.

### BACKGROUND

Silicon carbide (SIC) can be used to manufacture excellent power semiconductor devices with high breakdown voltage (BV) because its maximum critical electric field is about ten times higher than that of silicon (Si) and its energy band gap is about three times higher. Various studies on processes and structures are being conducted to implement silicon carbide power semiconductor devices, and among them, lateral power semiconductor devices are essential to be developed because they can be arranged in a plane and have the advantage of easy isolation between power semiconductor devices.

FIG. 1 is a cross-sectional view of a lateral insulated gate bipolar transistor (IGBT) based on silicon carbide (SIC) according to the prior art.

Referring to (a) of FIG. 1, a SIC-based lateral IGBT is formed using a semiconductor substrate in which an N− conductive type drift layer 20 made of SiC with a relatively low impurity concentration compared to the substrate 10 is formed on the upper surface of an N+ conductive type substrate 10 that forms a high-concentration impurity layer made of SiC.

A P conductive type body region 30 is formed on the upper layer of the drift layer 20, and an N+ conductive type emitter region 40 is formed on the upper layer of the body region 30 (i.e., an upper surface region of the semiconductor substrate).

In addition, a P conductive type collector region 50 is formed on the semiconductor substrate so as to be spaced apart from the body region 30 in a lateral direction.

An emitter metal layer 70 is formed on the upper surface of the semiconductor substrate to cover a portion of the emitter region 40 and the body region 30 adjacent to the emitter region 40, and a collector metal layer 90 is formed to cover the collector region 50.

In addition, a field insulating film 60 and a gate insulating film 65 are formed on the upper surface of the semiconductor substrate between the emitter metal layer 70 and the collector region 50 and spaced apart from each of the emitter metal layer 70 and the collector region 50.

Here, the gate insulating film 65 may be formed to cover another portion of the emitter region 40, the body region 30 adjacent to the emitter region 40, and the adjacent drift layer 20. The gate insulating film 65 is formed with a relatively small thickness compared to the field insulating film 60, and the field insulating film 60 and the gate insulating film 65 are formed to be connected to each other.

In order to form a channel, a poly gate electrode 80 is formed to cover the gate insulating film 65 and a portion of the field insulating film 60.

In this way, the SiC-based lateral IGBT has the advantage of easy placement of power semiconductor devices and isolation between power semiconductor devices since the emitter and collector are located on a plane.

In order for the SiC-based lateral IGBT to secure the targeted breakdown voltage in the breakdown voltage (BV) mode, as shown in (b) of FIG. 1, the collector region 50 must be located behind the position where the electric field intensity becomes 0 (zero) based on the position of the body region 30 (or the PN junction boundary).

However, in order to arrange the body region 30 and the collector region 50 with sufficient spacing L1 considering the electric field spreading, the chip size of the lateral IGBT must be increased, and there is also a problem that the loss increases.

The description of the technology behind this invention is provided for the purpose of understanding the background of the invention and is not intended to be a statement of the prior art known to those of ordinary skill in the art.

### DETAILED DESCRIPTION OF THE INVENTION

### Technical Objectives

The present invention is intended to provide a silicon carbide-based lateral power semiconductor device and a method for manufacturing the same, which can reduce the chip size by forming one or more trench buffer zones according to the breakdown voltage (BV) characteristics so that a body region and a collector region are arranged in close proximity in a lateral direction.

The present invention is intended to provide a silicon carbide-based lateral power semiconductor device and a method for manufacturing the same, which can selectively and easily implement a LIGBT (Lateral IGBT) or an RC (Reverse Conducting)-LIGBT according to an ion implantation technique for forming a collector region.

Other objects of the present invention will be easily understood through the following description.

### Technical Solution

According to one aspect of the present invention, there is provided a silicon carbide based-lateral power semiconductor device, including a substrate of a first conductive type formed of silicon carbide, a drift layer of the first conductive type formed on the substrate with a relatively low impurity concentration compared to the substrate, a body region of a second conductive type formed in an upper region of the drift layer, a collector region of the second conductive type formed in the upper region of the drift layer spaced apart from the body region in a lateral direction, and a trench buffer zone arranged between the body region and the collector region, for blocking field spreading in the lateral direction.

The trench buffer zone may include a buffer trench etched from an upper surface of the drift to a predetermined depth into the drift layer, a buffer insulating film filled in the interior of the buffer trench and a buffer region of the first conductive type formed to surround at least one of two sides and a bottom of the buffer trench when viewed in cross-section.

The trench buffer zone may be formed at a position relatively close to the collector region and the position is predetermined to secure a preset target breakdown voltage.

The buffer trench may be formed to a depth corresponding to ⅔ of the thickness of the drift layer

The buffer region may be formed with a relatively high impurity concentration compared to the drift layer

The buffer region may be formed by vertically and obliquely implanting ions of the first conductive type into the buffer trench.

The buffer trenches may be formed separately from each other in an island structure so as to be arranged in a direction perpendicular to a current path direction when viewed in plan, and the buffer regions may be formed to be continuous in a direction perpendicular to the current path direction when viewed in plan.

The collector regions may be formed in an island structure separated from each other so that they are arranged in a direction perpendicular to a current path direction when viewed in plan, and an anode region of the first conductive type formed with a relatively high impurity concentration compared to the drift layer may be formed between the separated collector regions.

More than two trench buffer zones are formed between the body region and the collector region, and more than two multiple trench buffer zones are formed to be in contact with each other.

The silicon carbide-based lateral power semiconductor device may further include a field insulating film formed on a portion of the drift layer located between the body region and the collector region so as to be connected to the buffer insulating film and a floating metal formed in a shape penetrating the field insulating film so as to connect a surface of the drift layer on the body region side and a surface of the drift layer on the collector region side separated by the trench buffer zone, wherein the buffer region may be formed to extend to a region where the floating metal and the drift layer on the body region side come into contact. The floating metal may form a second current path of a relatively shorter length compared to a first current path in the lower region of the trench buffer zone.

When viewed in cross-section, an electric field drop region of the second conductive type having a predetermined length may be formed in the upper region of the drift layer between the body region and the trench buffer zone

According to another aspect of the present invention, there is provided a method for manufacturing a silicon carbide-based lateral power semiconductor device, including forming, on a substrate of the first conductive type formed of silicon carbide, a drift layer of the first conductive type with a relatively low impurity concentration compared to the substrate, forming a buffer trench by etching from an upper surface of the drift layer into the drift layer to a predetermined depth, implanting ions of a second conductive type into an upper region of the drift layer using a predetermined first mask, thereby forming a body region of the second conductive type spaced apart from the buffer trench in a first direction and a collector region of the second conductive type spaced apart from the buffer trench in a second direction opposite to the first direction, and forming an emitter region by implanting ions of the first conductive type into an upper region of the body region using a preset second mask, and forming a buffer region surrounding at least one of two sides and a bottom of the buffer trench by vertically and obliquely implanting ions of the first conductive type into the buffer trench.

The method for manufacturing a silicon carbide-based lateral power semiconductor device of claim 13 may further includes forming a buffer insulating film to fill the inside of the buffer trench, and forming a field insulating film on the drift layer located between the body region and the collector region to be connected to the buffer insulating film and forming a floating metal in a shape penetrating the field insulating film to connect the surface of the drift layer on the body region side and the surface of the drift layer on the collector region side, which are separated by the buffer trench.

Aspects, features, advantages other than above described will be apparent from the following drawings, claims and detailed description.

### Effects of the Invention

According to embodiments of the present invention, by forming one or more trench buffer zones according to the breakdown voltage characteristics so that the body region and the collector region are arranged in close proximity in the lateral direction, there is an effect of significantly reducing the chip size.

In addition, there is also an effect of selectively and easily implementing LIGBT or RC-LIGBT depending on the ion implantation technique for forming the collector region.

### BRIEF DESCRIPTION OF ACCOMPANYING DRAWINGS

FIG. 1 is a cross-sectional view of a lateral insulated gate bipolar transistor (IGBT) based on silicon carbide (SIC) according to the prior art;

FIG. 2 is a cross-sectional view of a SiC-based LIGBT according to one embodiment of the present invention;

FIG. 3, FIG. 4 and FIG. 5 illustrate a process for manufacturing the SiC-based LIGBT according to one embodiment of the present invention;

FIG. 6 and FIG. 7 are cross-sectional views of SiC-based LIGBTs according to another embodiments of the present invention, respectively;

FIG. 8 is a plan view illustrating a shape of a trench buffer zone according to still another embodiments of the present invention;

FIG. 9 is a cross-sectional view and an example of I-V characteristics of a SiC-based RC-LIGBT according to still another embodiment of the present invention; and FIG. 10 is a cross-sectional view and an example of a current path during conduction of a SiC-based LIGBT according to still another embodiment of the present invention.

### MODE FOR INVENTION

The invention can be modified in various forms and specific embodiments will be described and shown below. However, the embodiments are not intended to limit the invention, but it should be understood that the invention includes all the modifications, equivalents, and replacements belonging to the concept and the technical scope of the invention. In describing the present invention, if it is determined that a detailed description of a related known technology may obscure the gist of the present invention, the detailed description thereof will be omitted.

Terms such as first, second, etc., may be used to refer to various elements, but, these elements should not be limited due to these terms. These terms will be used to distinguish one element from another element.

The terms used in the following description are intended to merely describe specific embodiments, but not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Same numbers refer to same or equivalent elements throughout the specification.

Relative terms, such as “below” or “above” or “upper” or “lower” or “horizontal” or “lateral” or “vertical” may be used herein to describe-one element, layer or region's relationship to another elements, layers or regions as illustrated in the Figures. It will be understood that relative terms are intended to encompass different orientations of the device in addition to the orientation depicted in the Figures.

Hereinafter, an embodiment of the present invention will be described in detail with reference to the accompanying drawings. However, in the following description, an insulated gate bipolar transistor (IGBT) will be mainly described, but it should be understood that the technical concept of the present invention may be applied and expanded to various types of semiconductor devices such as power MOSFET in the same or similar manner.

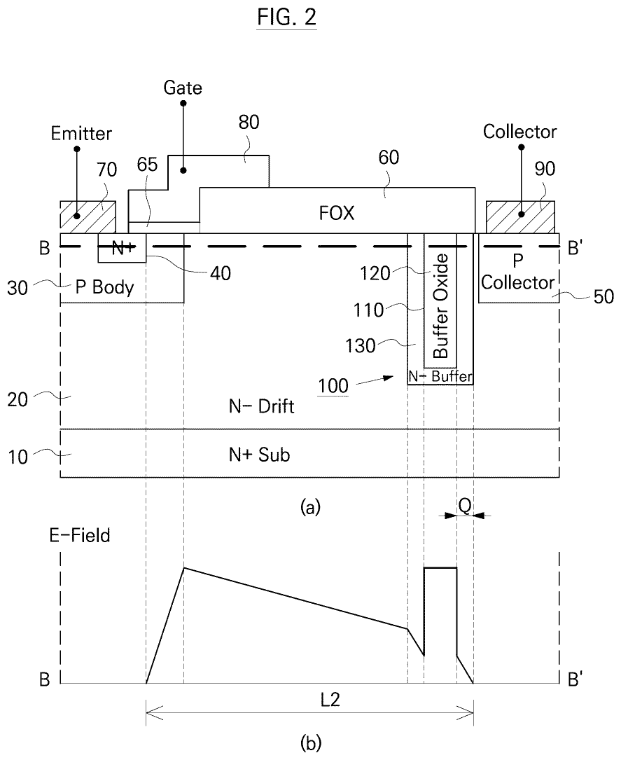

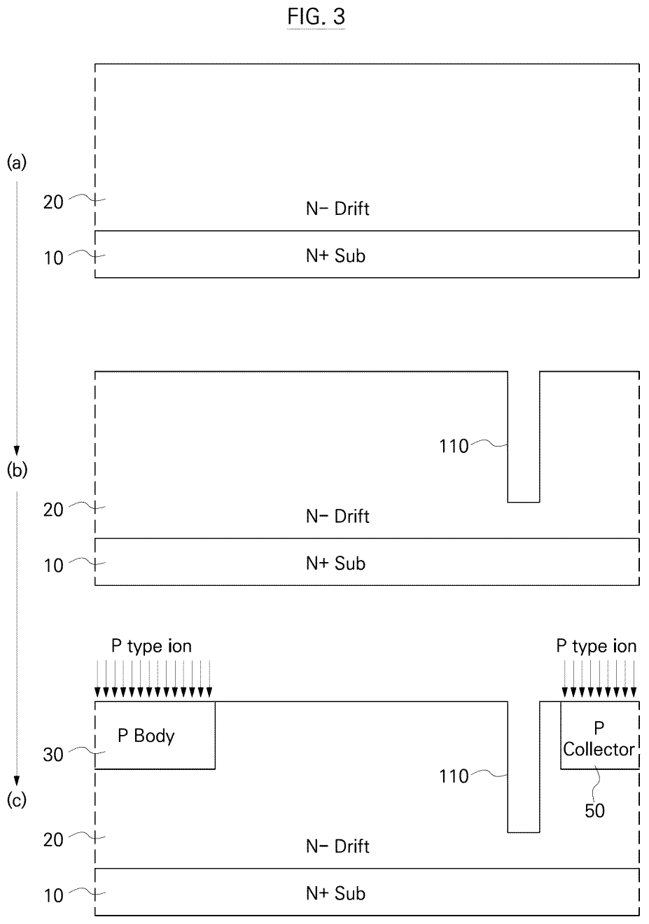

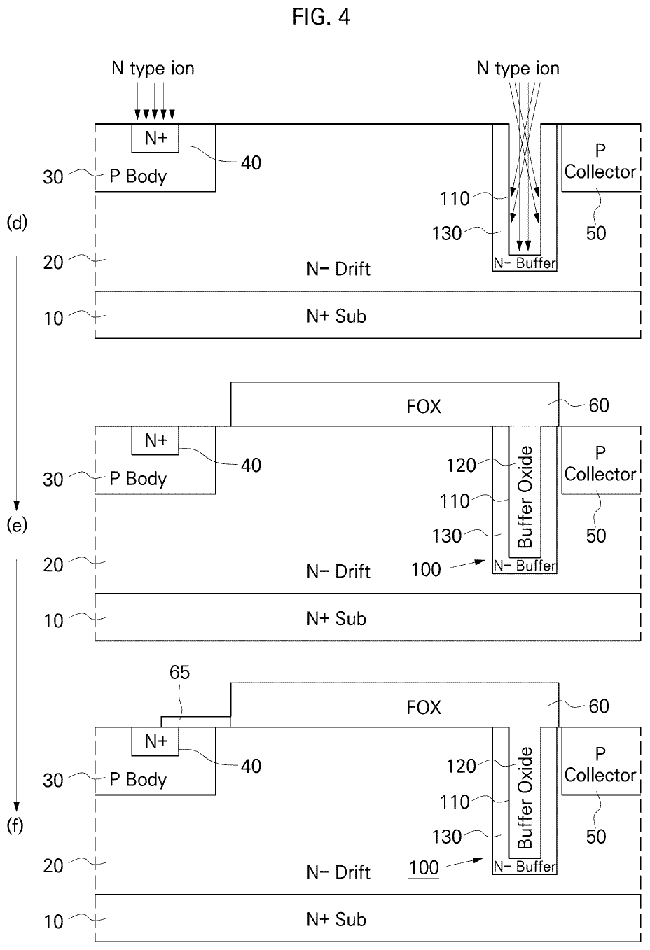

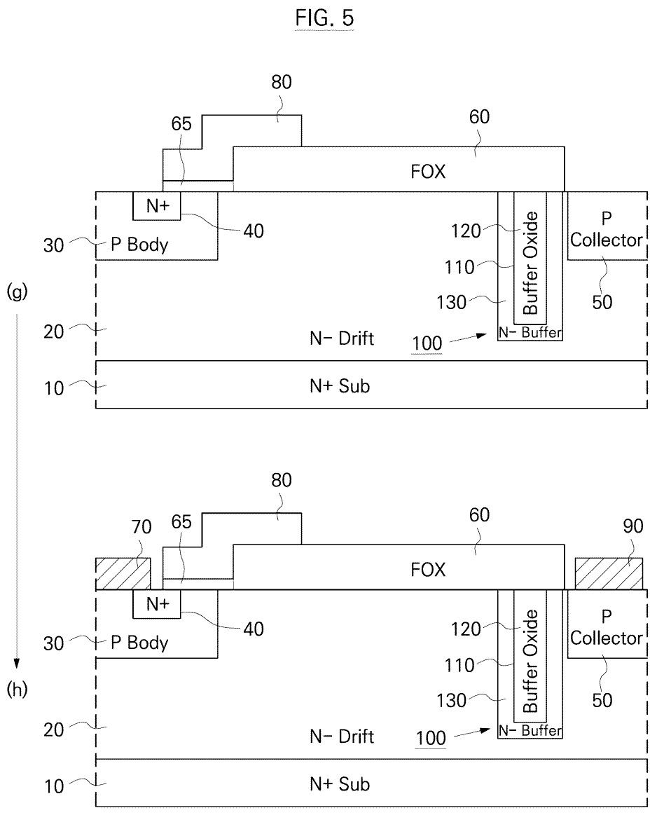

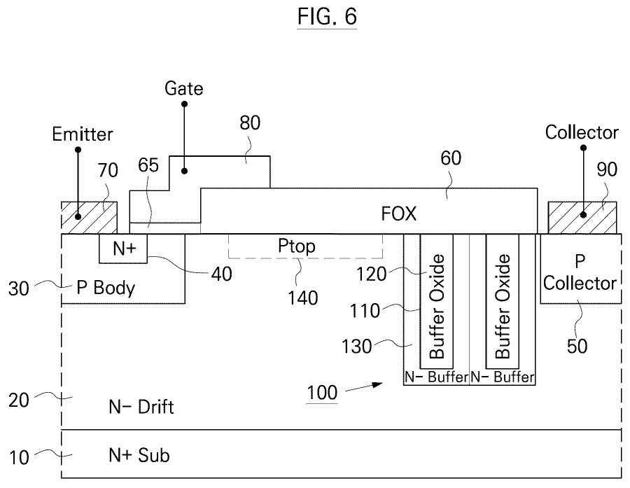

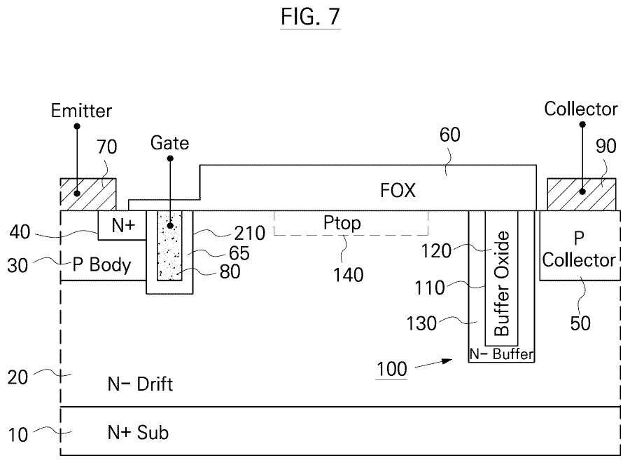

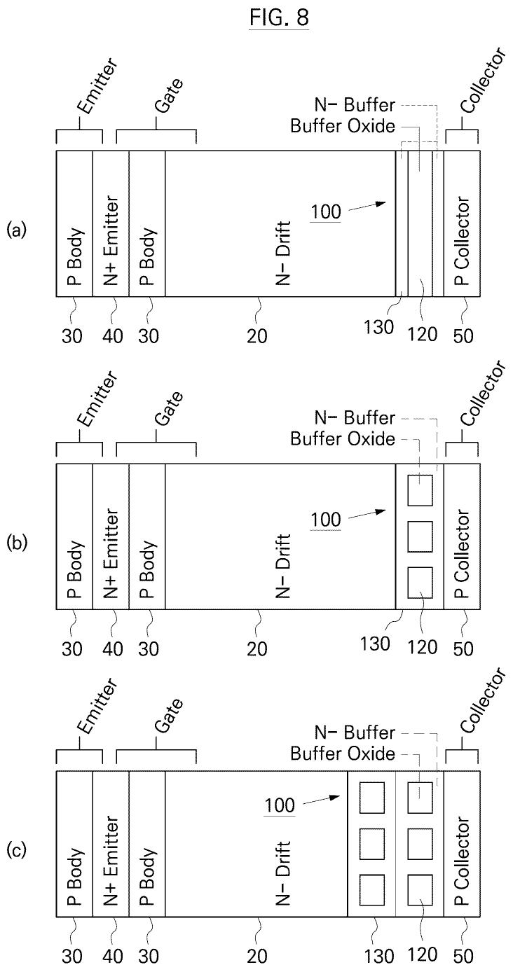

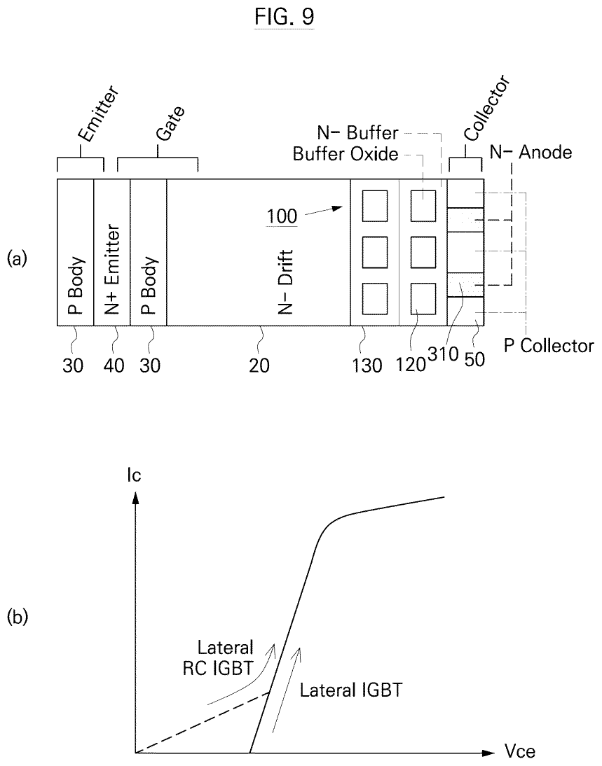

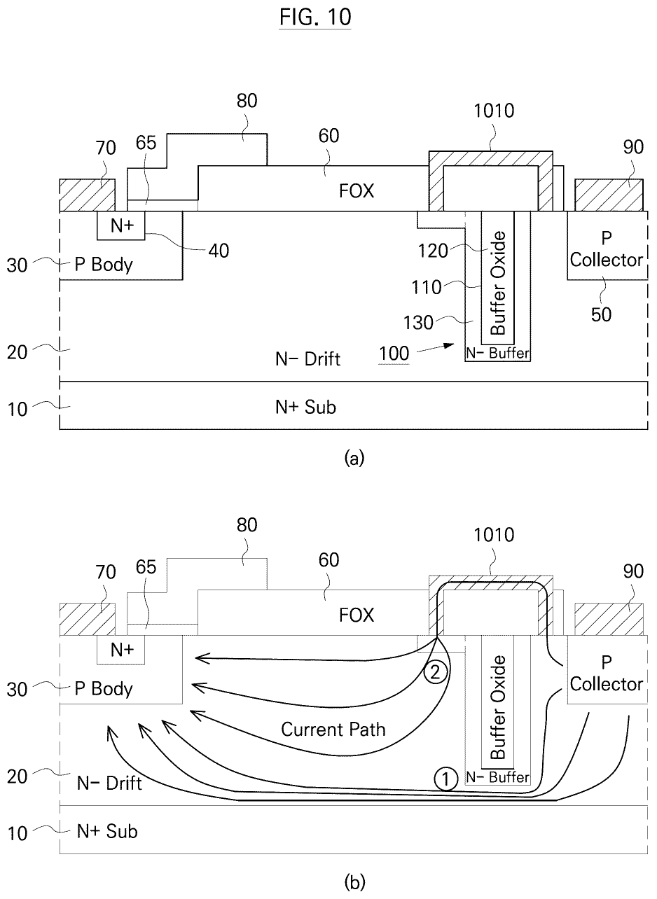

FIG. 2 is a cross-sectional view of a SIC-based LIGBT according to one embodiment of the present invention, FIGS. 3 to 5 illustrate a process for manufacturing the SiC-based LIGBT according to one embodiment of the present invention, and FIG. 6 and FIG. 7 are cross-sectional views of SIC-based LIGBTs according to another embodiments of the present invention, respectively. FIG. 8 is a plan view illustrating a shape of a trench buffer zone according to still another embodiments of the present invention, and FIG. 9 is a cross-sectional view and an example of I-V characteristics of a SiC-based RC-LIGBT according to still another embodiment of the present invention, and FIG. 10 is a cross-sectional view and an example of a current path during conduction of a SIC-based LIGBT according to still another embodiment of the present invention.

Referring to (a) of FIG. 2, a SiC silicon carbide-based lateral IGBT (LIGBT) may be formed using a semiconductor substrate in which an N− conductive type drift layer 20 made of SiC with a relatively low impurity concentration compared to an N+ conductive type substrate 10 is formed on an upper surface of the substrate 10 that is a high-concentration impurity layer made of SiC.

In cross-sectional view, a P conductive type body region 30 may be formed in the upper region of the drift layer 20, and an N+ conductive type emitter region 40 may be formed in the upper region (i.e., the upper surface region of the semiconductor substrate) of the body region 30. In addition, a P conductive type collector region 50 may be further formed in the upper region of the semiconductor substrate so as to be spaced apart from the body region 30 in the lateral direction.

Between the body region 30 and the collector region 50, a trench buffer zone 100 may be formed to block an electric field spreading from the emitter region 40 to the collector region 50 (i.e., electric field spreading in the lateral direction).

The trench buffer zone 100 may include a buffer trench 110 formed by etching from the upper surface of the semiconductor substrate to a predetermined depth into the drift layer 20, a buffer insulating film 120 filled in the interior of the buffer trench 110, and an N− conductive type buffer region 130 formed to entirely surround the side and bottom of the buffer trench 110. The buffer insulating film 120 may be formed of the same material as a field insulating film 60 described below.

For example, when it is assumed that a 1200V class SIC-based LIGBT is fabricated to have the drift layer 20 having a thickness of less than about 50% of that of a vertical IGBT of the same class, the buffer trench 110 may be formed with a depth of about 5 μm or less. For example, the buffer trench 110 may be formed with a depth corresponding to ⅔ of the thickness of the drift layer 20 and a width of 1 μm or less.

By implanting N conductive type ions into the buffer trench 110 using a vertical ion implantation technique and an inclined ion implantation technique, the N− conductive type buffer region 130 may be formed.

Considering the characteristic that the gradient of the electric field is proportional to the concentration, the buffer region 130 may be formed as an N− conductive type region with a relatively high ion concentration compared to the drift layer 20 so that the gradient of the electric field drops sharply before reaching the collector region 50 (see b of FIG. 2). For example, assuming a 1200V class power semiconductor device, if the drift layer 20 is formed at a level of less than 1e15/cm³, the buffer region 130 may be formed at a level of less than 1e16/cm³.

The SiC-based LIGBT according to one embodiment presents a distinctive structure in which the buffer region 130 is formed to continuously surround the side and bottom of the buffer trench 110.

This is because, while the buffer region 130 can be formed only with the ion implantation technique for silicon carbide materials, there is a limitation that prevents depths of more than a few um with typical process methods.

To overcome this limitation and form the buffer region 130 at a suitable depth, the buffer trench 110 may be first formed, and then high-concentration of N conductive type ions may be implanted using the buffer trench structure, so that the buffer region 130 can be formed at a relatively deep location.

Here, the buffer trench 110 for accommodating the buffer insulating film 120 inside may be formed to be continuous with a predetermined length as illustrated in (a) of FIG. 8, or may be formed by being separated into a plurality of islands arranged in a row as illustrated in (b) and (c) of FIG. 8, respectively. The buffer trenches 110 separated into a plurality of islands may be arranged in a row perpendicular to the current flow direction when viewed in plan.

As described above, since the trench buffer zone 100 formed between the body region 30 and the collector region 50 blocks the electric field spreading in the lateral direction, the collector region 50 may be arranged at a relatively close distance (L2 of (b) of FIG. 2) to the body region 30.

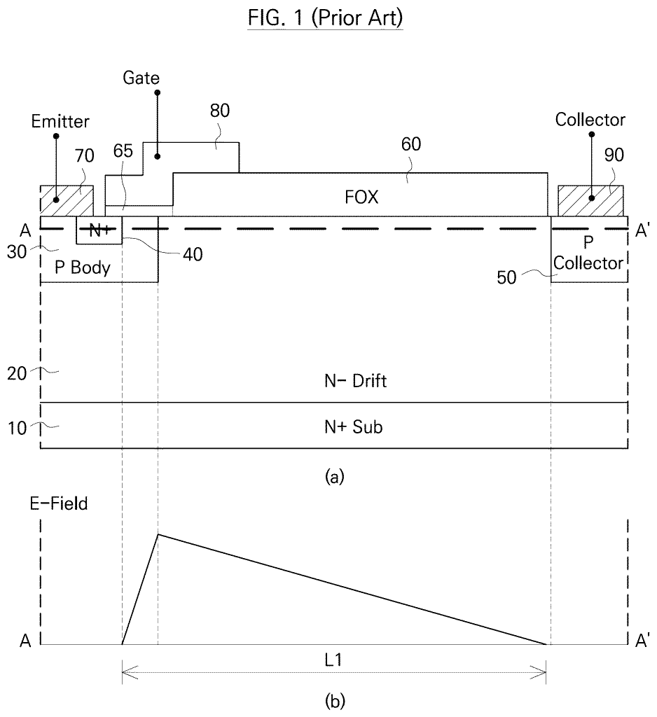

For example, in the case of a 1200V class LIGBT, the distance between the body region 30 and the collector region 50 can be set to less than 15 μm, which can be seen to be a significantly reduced distance compared to the distance between the body region 30 and the collector region 50 of the LIGBT according to the prior art in which the trench buffer zone 100 is not formed (see L1 of FIG. 1).

At this time, the trench buffer zone 100 can be arranged between the body region 30 and the collector region 50, at a position relatively close to the collector region 50. This is because the trench buffer zone 100 for blocking the lateral electric field spreading must be present at a position where a preset target breakdown voltage BV can be secured, and must also be positioned before the point where the lateral electric field becomes 0 (zero).

Specifically, when the trench buffer zone 100 is arranged relatively close to the body region 30, the breakdown voltage becomes relatively low, so that the trench buffer zone 100 can be positioned at a pre-designated position where the target breakdown voltage can be obtained. In addition, by arranging the collector region 50 so as to be close to the trench buffer zone 100, there is an advantage in that the withstand voltage characteristic is secured while also securing minimum loss in the conduction characteristics and switching characteristics.

In (a) of FIG. 2, a case is illustrated in which the buffer region 130 is formed to completely surround both sides and the bottom of the buffer trench 110 when viewed in cross section. However, depending on the gradient at which the electric field is reduced, the spacing between the trench buffer zone 100 and the collector region 50, and the like, the formation of the buffer region 130 may be omitted on the side surface (region Q of FIG. 2) of the buffer trench 110 adjacent to the collector region 50, so that the buffer region 130 may be formed in an L-shape instead of a U-shape when the LIGBT is viewed in cross-section.

In addition, an emitter metal layer 70 may be formed on the upper surface of the semiconductor substrate to cover a portion of the emitter region 40 and the body region 30 adjacent to the emitter region 40, and a collector metal layer 90 may be formed to cover the collector region 50.

Between the emitter metal layer 70 and the collector region 50, a field insulating film 60 and a gate insulating film 65 may be formed on the upper surface of the semiconductor substrate to be spaced apart from each of the emitter metal layer 70 and the collector region 50.

The gate insulating film 65 may be formed to cover the other portion of the emitter region 40 that is not covered by the emitter metal layer 70, the body region 30 adjacent to the emitter region 40, and the adjacent drift layer 20. The field insulating film 60 and the gate insulating film 65 may be formed to be connected to each other, and the gate insulating film 65 may be formed to have a relatively small thickness compared to the field insulating film 60 for smooth channel formation.

A poly gate electrode 80 may be formed to cover a portion of the gate insulating film 65 and the field insulating film 60 from above for channel formation.

In FIG. 2, the case where the poly gate electrode 80 is formed in a planar gate structure is illustrated, but it is obvious that the poly gate electrode 80 may also be formed in a trench gate structure as illustrated in FIG. 7. In FIG. 7, reference numeral 210 indicates a gate trench.

Referring to FIGS. 3 to 5, a process for manufacturing a SIC-based LIGBT according to one embodiment will be briefly described. A semiconductor substrate may be formed, on an N+ conductive type substrate 10 that forms a high-concentration impurity layer made of SIC, by epitaxially growing an N− conductive type drift layer 20 formed of SiC with a relatively low impurity concentration compared to the substrate 10 (see (a) of FIG. 3).

Next, a buffer trench 110 may be formed by etching from the upper surface of the semiconductor substrate into the drift layer 20 to a predetermined depth (see (b) of FIG. 3).

Next, by implanting P conductive type ions into the upper region of the drift layer 20 using a first mask (not shown) set in advance, a P conductive type body region 30 may be formed so as to be spaced apart in the first direction of the buffer trench 110 and a P conductive type collector region 50 may be formed so as to be spaced apart in the second direction, which is opposite to the first direction of the buffer trench 110 (see (c) of FIG. 3).

Next, by implanting N conductive type ions into the upper region of the body region 30 using a second mask (not shown) set in advance, an emitter region 40 may be formed, and N conductive type ions may be implanted into the buffer trench 110 using vertical implantation and oblique implantation techniques to form a buffer region 130 that entirely surrounds both sides and the bottom of the buffer trench 110 (see (d) of FIG. 4).

As described above, considering the gradient at which the electric field is reduced, the spacing between the trench buffer zone 100 and the collector region 50, and the like, the formation of the buffer region 130 may be omitted on the side of the buffer trench 110 adjacent to the collector region 50, so that the buffer region 130 may be formed in an L-shape instead of a U-shape.

Next, a buffer insulating film 120 may be formed to fill the interior of the buffer trench 110, and a field insulating film 60 may be formed to cover a portion of the upper surface of the drift layer 20 located between the body region 30 and the collector region 50 (see (e) of FIG. 4). The buffer insulating film 120 and the field insulating film 60 may be formed of the same material and may be formed in a T-shape that is connected to each other.

Next, a gate insulating film 65 may be formed on the upper surface of the semiconductor substrate so as to cover a portion of the emitter region 40, the body region 30 adjacent to the emitter region 40 and the adjacent drift layer 20 so as to be connected to the field insulating film 60 (see (f) of FIG. 4). Here, in order to enable smooth channel formation, the gate insulating film 65 may be formed with a relatively small thickness compared to the field insulating film 60.

Next, a poly gate electrode 80 may be formed to cover a portion of the field insulating film 60 and on the gate insulating film 65 (see (g) of FIG. 5).

In addition, an emitter metal layer 70 may be formed to cover the other portion of the emitter region 40 and the body region 30 adjacent to the emitter region 40 while being spaced apart from the gate poly gate electrode 80, and a collector metal layer 90 may be formed to cover the collector region 50 (see (h) of FIG. 5).

As described above, the SiC-based LIGBT according to one embodiment has the characteristic of forming one or more trench buffer zones 100 between the body region 30 and the collector region 50 to correspond to the breakdown voltage characteristics, thereby allowing the body region 30 and the collector region 50 to be arranged relatively close to each other in the lateral direction, thereby significantly reducing the chip size.

In order to block the lateral electric field spreading, the trench buffer zone 100 formed between the body region 30 and the collector region 50 is not limited to being formed as only one as shown in FIG. 2, and two or more trench buffer zones 100 may be formed between the body region 30 and the collector region 50 as shown in FIG. 6.

When two or more trench buffer zones 100 are formed, the width and depth of the buffer trenches 110 provided in each trench buffer zone 100 may be formed to be the same, but the width and depth of each buffer trench 110 are not necessarily limited to being the same.

In addition, each trench buffer zone 100 may be formed to be in contact with each other as shown in FIG. 6, but may also be formed to be spaced apart from each other by a predetermined interval.

In addition, in FIG. 6, while a case is illustrated in which the buffer regions 130 are formed to surround the buffer trenches 110 in a U-shape in both the first trench buffer zone 100 relative close to the collector region 50 and the second trench buffer zone 100 relative close to the body region 30, in order to share the buffer regions 130 arranged between the buffer trenches 110, the first trench buffer zone 100 may be formed in the U-shape, and the second trench buffer zone 100 may be formed in the L-shape.

In addition, as shown in FIG. 6 and FIG. 7, a P conductive type electric field drop region 140 may be further formed in the upper region of the semiconductor substrate between the body region 30 and the trench buffer zone 100 so as to be spaced apart from the body region 30 and the trench buffer zone 100.

The field drop region 140 may be formed in the upper region of the semiconductor substrate to lower the surface electric field. This is because, when the surface electric field is strong, mobile charges at the SiC/Oxide interface are moved and redistributed by the electric field, which causes breakdown voltage degradation and affects the life reliability of the power semiconductor device.

To this end, the field drop region 140 may be formed as long as possible to effectively lower the surface electric field, but it is obvious that it can be formed in any shapes that do not interfere with the current path.

FIG. 9 is a cross-sectional view of a SiC-based RC-LIGBT according to still another embodiment of the present invention.

As shown in (a) of FIG. 9, in forming the P conductive type collector regions 50, it is also possible to form a SiC-based RC (reverse conducting)-LIGBT with alternating P conductive type and N conductive type regions by forming a plurality of collector regions 50 separated from each other in an island shape such that the N conductive type drift layer 20 is exposed therebetween. In this case, the multiple collector regions 50, which are separated from each other in the form of islands when viewed in plan, may be arranged in a row in a direction perpendicular to the current path.

In order for the drift layer 20 exposed between the collector regions 50 separated from each other in the form of islands to be formed into an N conductive type anode regions 310, N conductive type ions may be implanted into the corresponding regions at a relatively higher ion concentration than the drift layer 20.

Referring to (b) of FIG. 9, briefly contrasting the characteristics of LIGBT and RC-LIGBT, LIGBT exhibits a diode-like turn-on characteristic that requires a bipolar turn-on voltage from the collector. In contrast, RC-LIGBT has characteristics of IGBT and MOSFET, so when Vce is 0 V or higher, MOSFET structure is turned on first, and then when Vce increases, IGBT structure is turned on, so it is possible to conduct current even at low Vce compared to LIGBT, and the conduction loss is relatively small.

FIG. 10 is a cross-sectional view of SiC-based LIGBT according to still another embodiment of the present invention.

As shown in FIG. 10, a floating metal 1010 may be formed in a shape that penetrates the field insulating film 60 to connect the drift layer 20 on the body region 30 side and the drift layer 20 on the collector region 50 side, which are separated relative to the trench buffer zone 100.

The floating metal 1010 not only provides an additional current path that bypasses the trench buffer zone 100, but also forms a second current path (path 2) with a relatively shorter length compared to the normal first current path (path 1)) corresponding to the lower region of the trench buffer zone 100. By the second current path additionally formed by the floating metal 1010, the situation in which the current flow is obstructed due to the formation of the trench buffer zone 100 can be significantly improved.

Since an electric field reaching the region where the floating metal 1010 and the drift layer 20 come into contact would cause a breakdown and a situation occurs where the high voltage can no longer be withstood, a buffer region 130 may be formed to extend to the region where the floating metal 1010 and the drift layer 20 come into contact in order to block the electric field spreading in the lateral direction.

In FIG. 10, a case is illustrated where the buffer region 130 is formed to extend only in the drift layer 20 on the body region 30 side connected to the floating metal 1010. This assumes a situation where the electric field does not reach the drift layer 20 on the collector area 50 side by the trench buffer zone 100, and if the electric field reaches the drift layer 20 on the collector area 50 side, it is natural that the buffer area 130 can be formed to extend in the drift layer 20 on the body area 30 side connected to the floating metal 1010.

Of course, regardless of whether the electric field reaches, it is obvious that the buffer area 130 can be formed to extend in the drift layer 20 on the collector area 50 side for the purpose of reducing the contact resistance with the floating metal 1010.

While the present invention has been described using the example of a power semiconductor device being an insulated gate bipolar transistor (IGBT), it is obvious that the technical ideas of the present invention may be equally or similarly applied and extended to other forms of power semiconductor devices, such as power MOSFETs.

Although the present invention has been described above with reference to embodiments thereof, it will be understood by those skilled in the art that various modifications and changes may be made to the present invention without departing from the spirit and scope of the present invention as set forth in the claims below.

1. A silicon carbide based-lateral power semiconductor device, comprising:
a substrate of a first conductive type formed of silicon carbide;
a drift layer of the first conductive type formed on the substrate with a relatively low impurity concentration compared to the substrate;
a body region of a second conductive type formed in an upper region of the drift layer;
a collector region of the second conductive type formed in the upper region of the drift layer spaced apart from the body region in a lateral direction; and
a trench buffer zone arranged between the body region and the collector region, for blocking field spreading in the lateral direction.

2. The silicon carbide-based lateral power semiconductor device of claim 1, wherein the trench buffer zone comprises:
a buffer trench etched from an upper surface of the drift to a predetermined depth into the drift layer;
a buffer insulating film filled in the interior of the buffer trench; and
a buffer region of the first conductive type formed to surround at least one of two sides and a bottom of the buffer trench when viewed in cross-section.

3. The silicon carbide-based lateral power semiconductor device of claim 2, wherein the trench buffer zone is formed at a position relatively close to the collector region, wherein the position is predetermined to secure a preset target breakdown voltage.

4. The silicon carbide-based lateral power semiconductor device of claim 2, wherein the buffer trench is formed to a depth corresponding to ⅔ of the thickness of the drift layer.

5. The silicon carbide-based lateral power semiconductor device of claim 2, wherein the buffer region is formed with a relatively high impurity concentration compared to the drift layer.

6. The silicon carbide-based lateral power semiconductor device of claim 2, wherein the buffer region is formed by vertically and obliquely implanting ions of the first conductive type into the buffer trench.

7. The silicon carbide-based lateral power semiconductor device of claim 2, wherein the buffer trenches are formed separately from each other in an island structure so as to be arranged in a direction perpendicular to a current path direction when viewed in plan,
wherein the buffer regions are formed to be continuous in a direction perpendicular to the current path direction when viewed in plan.

8. The silicon carbide-based lateral power semiconductor device of claim 1, wherein the collector regions are formed in an island structure separated from each other so that they are arranged in a direction perpendicular to a current path direction when viewed in plan,
wherein an anode region of the first conductive type formed with a relatively high impurity concentration compared to the drift layer is formed between the separated collector regions.

9. The silicon carbide-based lateral power semiconductor device of claim 1, wherein more than two trench buffer zones are formed between the body region and the collector region,
wherein more than two multiple trench buffer zones are formed to be in contact with each other.

10. The silicon carbide-based lateral power semiconductor device of claim 2 further comprises:
a field insulating film formed on a portion of the drift layer located between the body region and the collector region so as to be connected to the buffer insulating film; and
a floating metal formed in a shape penetrating the field insulating film so as to connect a surface of the drift layer on the body region side and a surface of the drift layer on the collector region side separated by the trench buffer zone,
wherein the buffer region is formed to extend to a region where the floating metal and the drift layer on the body region side come into contact.

11. The silicon carbide-based lateral power semiconductor device of claim 10, wherein the floating metal forms a second current path of a relatively shorter length compared to a first current path in the lower region of the trench buffer zone.

12. The silicon carbide-based lateral power semiconductor device of claim 1, wherein an electric field drop region of the second conductive type having a predetermined length is formed in the upper region of the drift layer between the body region and the trench buffer zone when viewed in cross-section.

13. A method for manufacturing a silicon carbide-based lateral power semiconductor device, comprising:
forming, on a substrate of the first conductive type formed of silicon carbide, a drift layer of the first conductive type with a relatively low impurity concentration compared to the substrate;
forming a buffer trench by etching from an upper surface of the drift layer into the drift layer to a predetermined depth;
implanting ions of a second conductive type into an upper region of the drift layer using a predetermined first mask, thereby forming a body region of the second conductive type spaced apart from the buffer trench in a first direction and a collector region of the second conductive type spaced apart from the buffer trench in a second direction opposite to the first direction; and
forming an emitter region by implanting ions of the first conductive type into an upper region of the body region using a preset second mask, and forming a buffer region surrounding at least one of two sides and a bottom of the buffer trench by vertically and obliquely implanting ions of the first conductive type into the buffer trench.

14. The method for manufacturing a silicon carbide-based lateral power semiconductor device of claim 13 further comprises:
forming a buffer insulating film to fill the inside of the buffer trench, and forming a field insulating film on the drift layer located between the body region and the collector region to be connected to the buffer insulating film; and
forming a floating metal in a shape penetrating the field insulating film to connect the surface of the drift layer on the body region side and the surface of the drift layer on the collector region side, which are separated by the buffer trench.
